(19) United States
(12) Patent Application Publication
(10) Pub. No.: US 2004/0195938 A1
(43) Pub. Date: Oct. 7, 2004

(54) Power conversion module

(76) Inventor: Itzhak M. Itzhaky, Columbus, OH (US)

Correspondence Address: SHANKS & HERBERT, 1301 K STREET, N.W., SUITE 1100 - EAST TOWER, WASHINGTON, DC, 20005, US

(21) Appl. No.: 10/814,251

(22) Filed: Apr. 1, 2004

Related U.S. Application Data
(60) Provisional application No. 60/459,620, filed on Apr. 3, 2003.

(51) Int. Cl. H02N 2/00; H01L 41/04

(52) U.S. Cl. 310/328

(57) ABSTRACT

A power conversion module comprises a stack-piezo disposed in a housing between a mechanical stop and a moveable piston adjacent a sealed chamber containing a fluid. The mechanical stop biases the stack-piezo expansion direction. An energized stack-piezo expands and moves the piston, which in turn applies compressive force to the fluid in the sealed chamber. The forces applied to the fluid displaces a shaft slidably mounted in a channel formed in the chamber. A biasing means returns the shaft to its starting position when the piezo is de-energized. The sealed chamber preferably has a large diameter adjacent the piston, and a smaller diameter opening for the channel, through which the shaft moves. Preferably, the sealed chamber mostly has a frustoconical shape. The shaft deflection distance may be varied by altering the ratio of the fluid-exposed surface area of the piston to that of the shaft and altering the stack-piezo's length.

### RELATED APPLICATIONS

This application claims the benefit of Provisional Application No. 60/459,620, filed Apr. 3, 2003.

### BACKGROUND OF THE INVENTION

1. Field of the Invention

The present invention relates to power modules, and more particularly to power modules converting electrical energy to mechanical energy.

2. Brief Description of the Related Art

Several devices are known that convert electrical energy into mechanical energy. These devices are most often used for changing positions of switches, valves, and the like in electromechanical systems. One such device is a solenoid. A solenoid uses electrical energy to create a magnetic field, which in turn moves a plunger or piston. Solenoids typically operate at a high current, consuming power, and releasing wasted energy through heat. The heat damages and breaks down solenoid materials, resulting in a short solenoid operating life. Thus, solenoids are problematic because they are undependable, and increase maintenance time and costs.

Other power conversion modules for electromechanical systems use piezo valves. In a piezo valve device, piezo material, typically ceramic or crystalline, deforms when electrically charged. The material's expansion is used to apply force to a lever, piston, or the like, and change valve states, e.g., to open or closed. The force applied to the piston, and any accompanying deflection affect the mechanism's operating characteristics. Piezo valves generally operate under a low power consumption, which is efficient. However, currently known piezo applications tend to generate either a low deflection and a high force, or a high deflection and a low force. For example, Bender type piezos typically produce a low force and a high deflection of a few millimeters. Stack-piezos typically produce a high force of a few thousand newtons, while delivering a deflection of only a few microns. Having only either high or low force delivery, current devices are too limited for many applications.

Although current electromechanical control mechanisms generally function well, they have not provided reliable control mechanisms which last for long periods of time. Current power conversion modules further do not provide a single apparatus with a sufficient balance of force and movement or deflection to be useful in a wide range of applications.

### SUMMARY OF THE INVENTION

A power conversion module which converts the high force of a stack-piezo at expansion and its low expansion rate into lower force and higher useable expansion is provided. The power conversion module comprises a stack piezo disposed in a housing between a mechanical stop and a moveable piston that is adjacent to a sealed chamber containing a non compressible fluid. The mechanical stop biases the stack piezo expansion direction. When energized, expansion of the stack-piezo presses against and moves the piston, which in turn applies compressive force to the non compressible fluid in the adjacent sealed chamber. The forces applied to the fluid displaces a shaft that is slidably mounted in a channel formed in the chamber. The shaft movement can be utilized to change the state of an apparatus such as a switch or valve. A biasing means returns the shaft to its starting position. The sealed chamber preferably has a large diameter at the distal end adjacent the piston, and a smaller diameter opening for the channel at the proximal end through which the shaft moves. Preferably, the sealed chamber mostly has a frustoconical shape. The shaft deflection distance may be varied by altering the ratio of the fluid-exposed surface area of the piston to that of the shaft.

Still other objects, features, and attendant advantages of the present invention will become apparent to those skilled in the art from a reading of the following detailed description of embodiments constructed in accordance therewith, taken in conjunction with the accompanying drawings.

### BRIEF DESCRIPTION OF THE DRAWINGS

The invention of the present application will now be described in more detail with reference to preferred embodiments of the apparatus, given only by way of example, and with reference to the accompanying drawings, in which:

FIG. 1 illustrates a sectional view of a preferred embodiment according to the present invention.

FIG. 2 illustrates fluid flow in a preferred embodiment in accordance with the present invention.

FIG. 3 illustrates fluid flow in an alternative embodiment in accordance with the present invention.

FIG. 4 illustrates a sectional view of a preferred embodiment in accordance with the present invention.

FIG. 5 illustrates an alternative embodiment in accordance with the present invention.

### DESCRIPTION OF THE PREFERRED EMBODIMENTS

Referring to the drawing figures, like reference numerals designate identical or corresponding elements throughout the several figures.

The present invention has been made in view of the above circumstances and provides, among other things, a power conversion module that converts electrical energy to mechanical energy. The present invention provides a power conversion module that delivers a range of mechanical force and deflection that is commonly useable in control systems, and particularly adaptable to valve control. The present invention further provides a reliable power conversion module that delivers commonly useable force values while operating at a low current. The present invention further provides a power module generally delivering about 1 to 1000 newtons of force from the piezo and a shaft useable movement of approximately 1 to 5 millimeters.

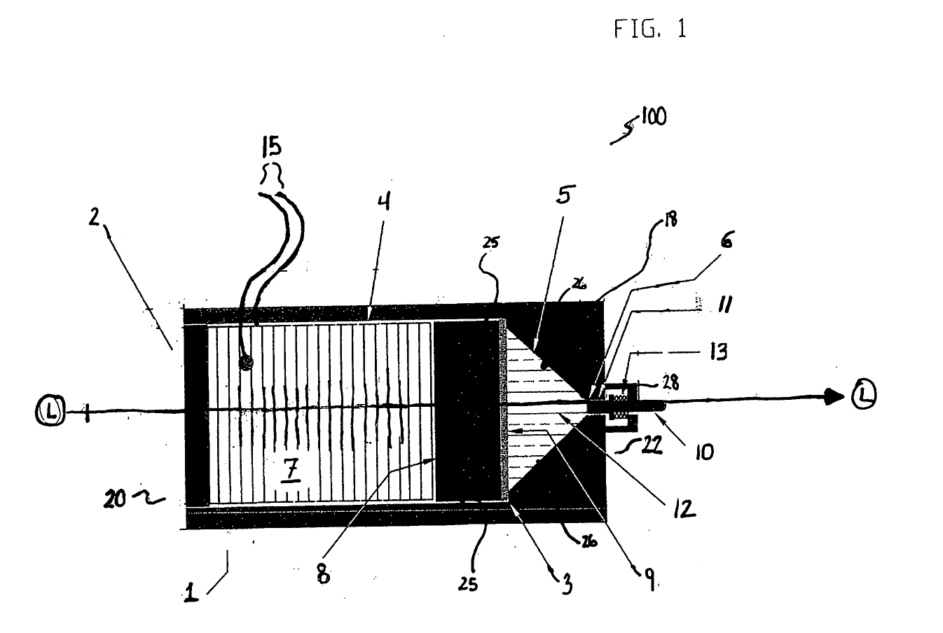

Referring to FIG. 1, a sectional view of a preferred embodiment of a power conversion module 100 according to the present invention is illustrated. A housing 1 has a distal end 20 and a proximal end 22. The housing 1 at least partially encases components of the power conversion module 100. Components contained within the housing 1 referred to as having a distal end and a proximal end refer to the end of a component closest to the distal end 20 or proximal end 22 of the housing. Within the housing 1 there are several chambers 4, 5. The shape of the housing 1 and components contained therein, further described below, define the shape of each chamber 4, 5. Preferably, the housing 1 and chambers 4, 5 are generally cylindrical. However, it will be appreciated by one of ordinary skill in the art that various geometrical configurations, such as having cross-sections that are square, rectangular, etc., or combinations thereof, may be used without departing from the scope of the present invention. Housing 1 may be constructed from any material that has sufficient structural integrity to withstand the temperatures and pressures to which the power module 100 is subjected during use. For most applications, the housing 1 may be constructed from hard plastic, which is cost-effective and light-weight while providing good insulation and sealing properties. However, aluminum, stainless steel, ferrous metals, and other metals, while less preferred, may also be used to construct the housing 1. If the housing 1 is made of conductive materials, it should be grounded in accordance with UL standards.

Proceeding along longitudinal axis L, from distal end 20 to proximal end 22, a mechanical stop 2, stack-piezo 7 and piston 8 are contained in first chamber 4. Mechanical stop 2 is positioned within the first chamber 4 at the distal end 20 of the housing 1. Mechanical stop 2 preferably contacts and exerts slight pressure on the stack piezo 7 at its distal end, causing the stack-piezo 7 to expand toward the proximal end 22 of the housing along longitudinal axis L when energized. Preferably, mechanical stop 2 provides sufficient pressure such that stack-piezo 7 exerts approximately from 1 to 10 newtons on the piston 8 in a resting state. Mechanical stop 2 is preferably a plug. However, it will be appreciated by one of ordinary skill in the art that a wide variety of mechanisms, for example, a spring ring may be used without departing from the scope of the present invention.

Connecting wires 15 attach to the stack-piezo 7, preferably towards the distal end 20, to facilitate the application of electrical energy to further bias the stack-piezo 7 to expand along longitudinal axis L. The connecting wires 15 feed through small, filled holes (not shown) in the housing 1 and connect to any type of electrical source (not shown) to energize the stack piezo 7. Typically, stack-piezos 7 can be energized with a direct current (DC) voltage ranging from about 50 to 500 volts, DC. Increasing the energizing voltage increases the stack-piezo's 7 rate of expansion and the amount of force the stack-piezo 7 delivers. Stack-piezos 7 are widely available commercial products. One example of a stack-piezo 7 suitable for use with the present invention is the Stacked Ceramic Multilayer Actuator made by Noliac A/S of Denmark.

Still proceeding along longitudinal axis L, piston 8 lies in direct contact with the proximal end of stack-piezo 7, between the first chamber 4 and a second chamber 5. Second chamber 5 is a sealed chamber and contains a non-compressible fluid 12. First sealing means prevents any non-compressible fluid from migrating from the second chamber 5, past the piston 8, and into the first chamber 4. First sealing means is preferably a step 3 and seal 9 combination. Step 3 provides a seat for seal 9, and may be formed as a recess in the housing adjacent the second chamber. Seal 9 is preferably constructed from a resilient material such as rubber that resists the force applied by piston 8, but also absorbs additional force when the stack-piezo 7 is first energized. Seal 9 is preferably a ring seal. Seal 9 only needs to prevent migration, and does not need to cover the surface area of the portion of the piston facing the second chamber 5. Alternatively, first sealing means may be a groove and ring seal combination. It will be appreciated by one of ordinary skill in the art that a wide variety of objects and/or constructs may be used singly or in combination as a means for sealing the first chamber and preventing fluid from migrating from the second chamber 5 to the first chamber 4.

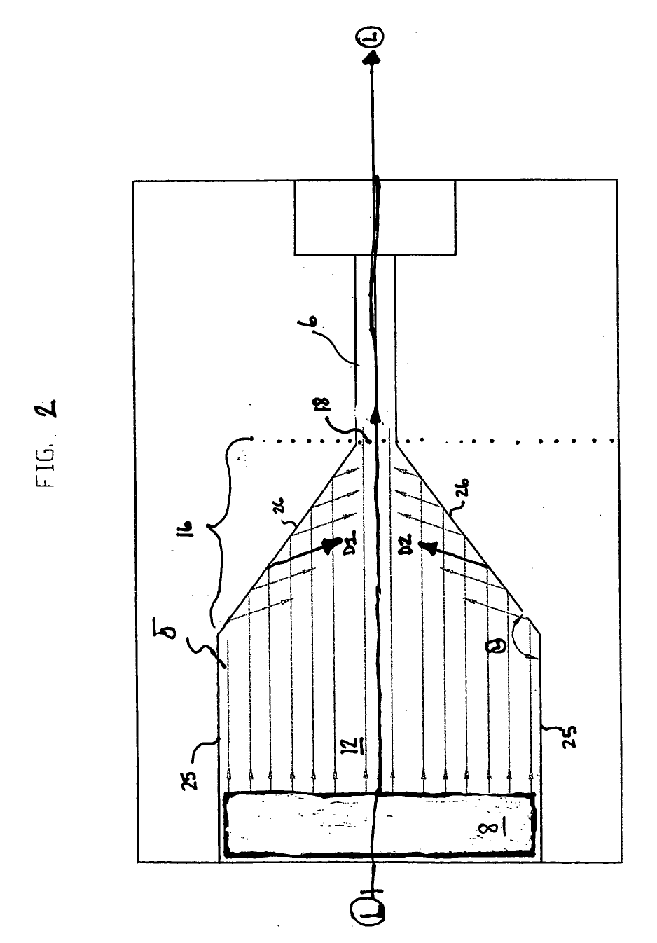

The shape of second chamber 5 is mostly defined by at least one side wall 25 and at least one front wall 26. Second chamber 5 contains a fluid 12 which receives force from the piston 8. The volume of second chamber 5 remains essentially fixed because piston 8 displaces by only a few microns. Preferably, the fluid 12 is a non-compressible fluid, such as hydraulic fluid, which maximizes the amount of force transfer when compressive forces are applied. Second chamber 5 has an opening 18 within front wall 26, and a channel 6. Opening 18 is preferably of smaller diameter than that of the distal end of chamber 5 adjacent to piston 8. As one skilled in the art will recognize, the size of opening 18 in relation to the larger diameter of the second chamber 5, can be varied depending on the needs for deflection and usable force at shaft 10. As illustrated in FIGS. 1 and 2, the front wall 26 of the second chamber 5 tapers preferably into a frustoconical portion 16, towards the proximal end 22 of the housing 1 along longitudinal axis L. The frustoconical portion 16 tapers to opening 18, which allows fluid to flow into a channel 6. Optionally, when second chamber 5 is constructed with a frustoconical section, the second chamber 5 may be formed with only front walls 26 and no side walls 25.

Referring again to FIG. 1, the channel 6 extends along longitudinal axis L from the small opening 18 of the second chamber 5. Channel 6 partially contains shaft 10 and fluid 12, so that shaft 10 moves freely along longitudinal axis L. A second sealing means 11 is disposed in the channel 6 and surrounds the shaft 10. The second sealing means 11 prevents fluid from leaving the second chamber 5 at the proximal end of the channel 6. Preferably, the second sealing means 11 is a rubber o-ring. O-rings made from another suitable material, namely, reinforced wax and cotton combination, may also be used with the present invention. However, it will be appreciated by one of ordinary skill in the art that other objects and/or constructs may be used singly or in combination as a second sealing means 11 which prevents fluid from migrating out of second chamber 5 through the channel 6.

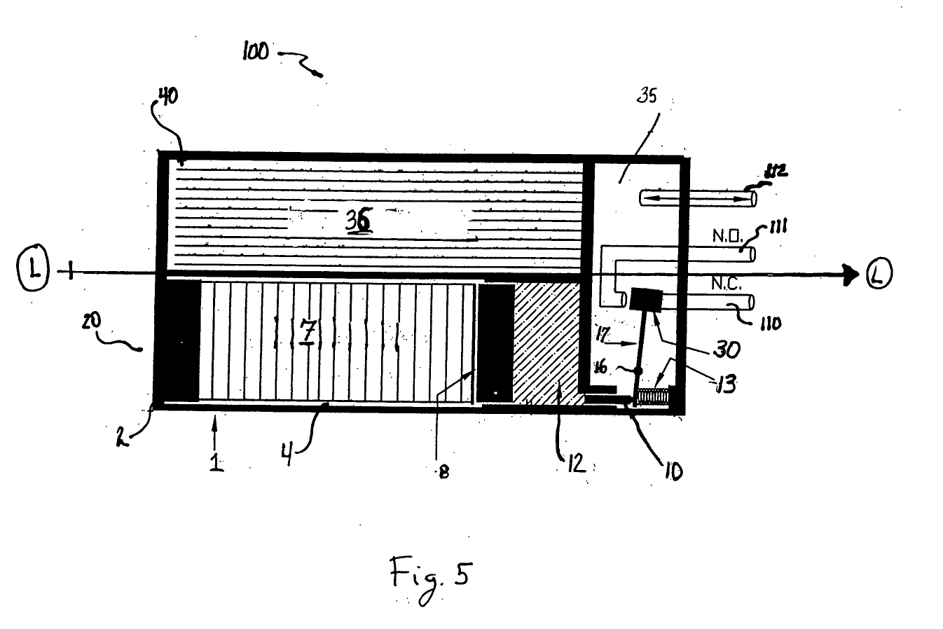

Shaft 10 extends from channel 6, and through shaft guard 28. A biasing means 13 applies slight pressure to the shaft 10 that will not resist pressure from the stack piezo 7 and piston 8 when energized. However, the biasing means 13 exerts sufficient pressure to return the shaft 10 toward distal end 20 along longitudinal axis L when the stack-piezo 7 is de-energized. Preferably, biasing means 13 is a return spring. However, it will be appreciated by one of ordinary skill in the art that other mechanisms and sources of air or water pressure are suitable biasing means without departing from the scope of the present invention. For example, the alternative embodiment of FIG. 5 further discussed below illustrates a biasing means external to the housing 1. Since second chamber 5 is sealed, shaft 10 can be used to move any sort of valve or object, including but not limited to pneumatic or hydraulic control valves and switches.

The power converter 100 operates as follows. The stack-piezo 7 is energized from an electrical source through connecting wires 15. Mechanical stop 2 biases the stack-piezo 7 to fit tightly against piston 8, and to expand along longitudinal axis L. As stack-piezo 7 expands, it exerts force on piston 8. Piston 8 in turn travels along longitudinal axis L and imparts compressive force to fluid 12. The piston 8 displaces by a few micrometers, typically ranging from 5 to 20 micrometers. The force exerted on fluid 12 bears directly on to shaft 10, pushing shaft 10 along longitudinal axis L, until shaft 10 extends away from its resting position and further from the proximal ends of channel 6 and shaft guard 28. The movement of the shaft 10 is then used to move any object requiring an on/off state, such as opening or closing valves or electrical contacts, as is widely known in the art. When the electrical signal applied by connecting wires 15 is reversed or shorted, the stack-piezo 7 retracts back to its original size, withdrawing and relieving compressive force applied to the fluid 12. Biasing means 13 forces the shaft 10 back to its original starting position when the stack-piezo 7 is no longer exerting force against the piston 8 and fluid 12.

As previously discussed, pressure and force application is altered within the present invention to achieve various results. First, force application can be affected by the shape of the fluid chamber. Second, force application can be affected by the dimensions of various items in the path of force delivery.

Referring to FIG. 2, fluid flow in a preferred embodiment of the second chamber is illustrated. In this embodiment, the force of piston 8 against fluid 12 creates shock waves. The shock waves flow through the fluid 12 as illustrated by arrows parallel with longitudinal axis L. When the shock waves reach the frustoconical portion 16, the frustoconical portion 16 deflects the shock waves in the direction illustrated by arrows D1 and D2. Particularly, shock waves are deflected toward the center of the module 100 and also toward shaft 10. This deflection applies some of the shock wave energy to moving shaft 10. The measurement of angle θ between the side wall 25 and front wall 26 preferably ranges between 90 to approximately 150 degrees. More preferably, angle θ measures between approximately 130 to approximately 150 degrees to form the frustoconical shape, and most preferably measures about 145 degrees. It will be appreciated that changing the position of the front wall 26 such that angle θ measures over 150 degrees, lengthens the power module considerably, and makes the device longer than may be useful for many practical applications. In embodiments where second chamber 5 does not have at least one sidewall 25, angle θ is measured between the front wall 26 and the plane of the surface of piston 8 in contact with second chamber 5.

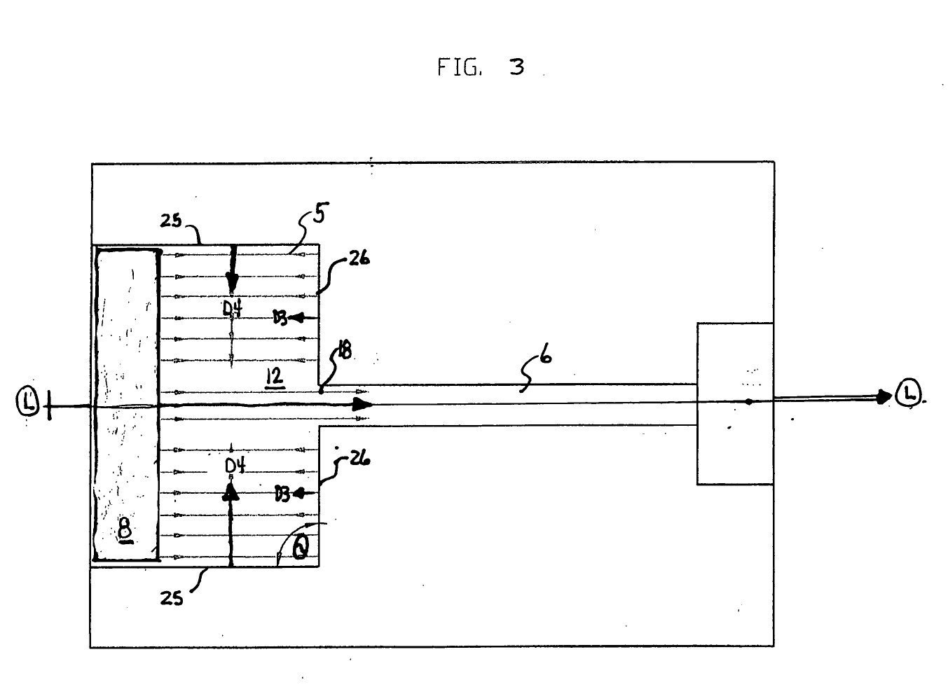

Referring to FIG. 3, fluid flow in an alternative embodiment according to the present invention is illustrated. Similar to FIG. 2, actuating the piston 8 causes shock waves to flow through the fluid 12 as illustrated by arrows parallel with longitudinal axis L. In this embodiment, the front wall 26 and side walls 25 are separated by an angle θ of 90 degrees. When the shock waves reach the front wall 26, they are deflected in the opposite direction, as illustrated by the arrows D3. The flow illustrated by D3 then causes the additional shock wave flow illustrated by arrows D4. Shock waves generated by movement of piston 8, will travel in a straight line toward front wall 26 and are then deflected back toward the distal end 20. Equal pressure between piston 8 and front wall 26 applies pressure to the non compressible fluid 12, causing the shockwaves to move in the direction of arrow D4 and then in longitudinal line L.

In order to create a useable physical movement, the force delivered by shaft 10 is determined by the diameter of the shaft 10 and the larger diameter of the second chamber 5 at its distal end. Particularly, the distance of the shaft 10 deflection is directly related to the amount of non compressible fluid 12 displaced by the piston 8 when the stack-piezo 7 expands. The volume of the hydraulic fluid is determined by the size of chamber 5, which is determined by the required force and deflection of shaft 10. For example, where a stack piezo measures 7×7×7 millimeters (mm) in length, width, and depth, a piston diameter of about 9.9 mm provides a surface area exposed to the hydraulic fluid 12 of about 6.63 millimeters, assuming an arbitrarily chosen reduction of ⅓ of the total surface area for step 3. The ratio of the surface area of the piston 8 exposed to fluid 12, which controls the volume of fluid 12 displaced by movement of the piston 8 to the surface area of the cross-section of the shaft 10 inside of the housing in combination with the expansion of the stack-piezo 7, determines the distance the shaft 10 travels away from the proximal end 22 of the housing 1 or otherwise out of the sealed chamber 5.

Currently, commercially available stack-piezos 7 have various dimensions. Typically, a stack-piezo 7 is shaped as a square solid with a cross section of up to 50 mm in both length and width. However, it will be appreciated that stack-piezos can be constructed in a rectangular, cylindrical, and other geometric configurations. An exemplary, 50×50×50 millimeter stack-piezo 7 expands approximately 60 micrometers, and exerts approximately 150,000 newtons. The diameter of the shaft 10 is determined by calculating the displacement of fluid 12 required to displace the shaft 10 with the requisite blocking force. Such calculations are well known by one of ordinary skill in the art. This exemplary configuration can provide a shaft 10 deflection of 5 millimeters, with a shaft diameter of 5.2 millimeters, and may produce a blocking force of up to 1800 newtons.

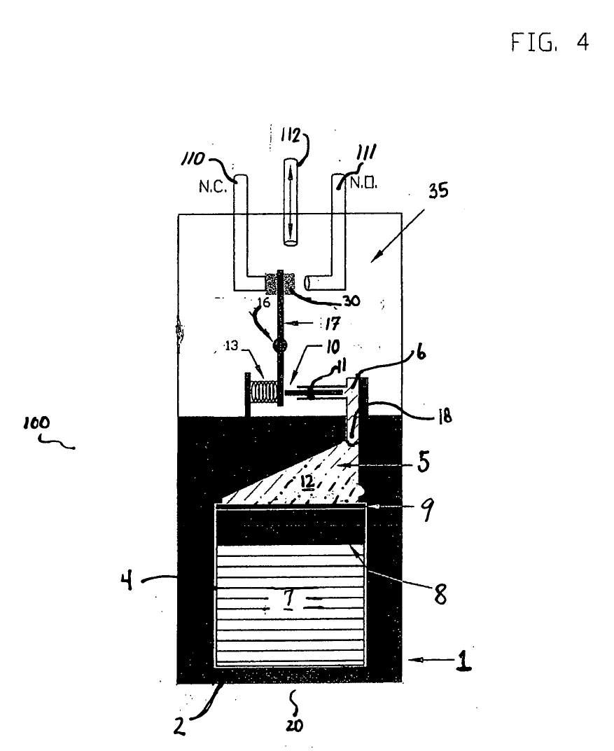

Referring to FIG. 4, a sectional view of an additional embodiment in accordance with the present invention is illustrated. This embodiment illustrates biasing means 13 as an outside load, and a dimension configuration fitting commonly available stack-piezos. In an exemplary embodiment, the stack-piezo 7 measures 7 mm×7 mm x10 mm. Piston 8 has a diameter of 9.9 mm, corresponding to the diagonal length of the base of stack-piezo 7, and having a surface area of 35 square millimeters in contact with hydraulic fluid 12, where the step 3 is arbitrarily chosen as covering approximately 1/3 of the piston diameter. Shaft 10 is 0.59 millimeters in diameter, presenting a contact area at each end of 0.27 square millimeters. These dimensions are based on required deflection of 1.5 mm. Step 3 is selected as having an area of 67% of the diameter of first chamber 4. However, as previously discussed, if a step is included in first sealing means, any size sufficient to prevent fluid migration between first chamber 4 and second chamber 5 is sufficient. The second chamber 5 larger diameter would then be 6.6 mm, presenting an area of 34 square mm. When stack-piezo 7 is energized, it expands 10 micrometers and provides a blocking force of 3000 newtons. The volume of hydraulic fluid 12 displaced is 0.034 cubic millimeters. To accommodate this volume, shaft 10, which is 0.59 mm in diameter, is displaced a length of 1.5 millimeters. Increasing or decreasing the diameter of shaft 10, as well as decreasing or increasing the diameter of piston 8 and the larger diameter of second chamber 5, will change the distance traveled and force applied by the shaft 10 accordingly.

Shaft 10 extends from channel 6 into a third chamber 35. Second sealing means 11 prevents fluid from migrating out of channel 6 and into third chamber 35. Biasing means 13 is positioned such that shaft 10 only makes surface contact and does not exert pressure when stack piezo 7 is in a non-energized state. With the dimensions discussed above, shaft 10 is displaced from channel 6 delivering a blocking force of 23.5 Newtons. Shaft 10 pushes the section of lever 17, which is pressed against it by return spring 13. The other section of lever 17, rotates about pivot 16. The rotation of lever 17 releases the pressure applied by seal 30 on tube 110 and applies pressure on tube 111. The movement of seal 30 thereby alternates the flow of fluid between tube 112 and tubes 110 and 111. Changing the location of pivot 16 on lever 17 either decreases or increases the travel length and force of seal 30.

FIG. 5 illustrates an alternative embodiment of the present invention. Particularly, an electronic driver 36 is incorporated into the power module 100. Electronic driver 36 accepts any signal, typically between 5 to 48 volts direct current (DC) or 110 to 230 volts alternating current (AC) from a source outside the power module 100, for example, from a control system, or otherwise as is well known by one of ordinary skill in the art. The electronic driver 36 is preferably contained within a fourth chamber 40, with a second set of connecting wires (not shown) between the electronic driver 35 and some outside signal source (not shown). The electronic driver 36 can optionally be contained within first chamber 4, but is kept separate or otherwise not in physical contact with stack-piezo 7, so as not to interfere with expansion of stack-piezo 7. The driver 35 converts the source signal to a signal that can be sent to the stack-piezo 7. A second set of connecting wires (not shown) simply electrically connect the electronic driver 36 and the stack-piezo 7. The power conversion module 100 of this embodiment is otherwise constructed and operated as described above.

In each of the embodiments described herein, it is preferred that the stack-piezo 7, the piston 8, the shaft 10, and smaller opening 18 are proximally aligned at a center point along longitudinal axis L. The force exerted by or through each component is most efficiently translated in such an arrangement. However, it will be appreciated by one of ordinary skill in the art that proximally off-setting the components, though less preferred, is still within the scope of the present invention.

In an additional embodiment of the present invention, piston 8 may be removed, and the proximal end of the stack-piezo 7 seats directly against the first sealing means and the non compressible fluid 12.

Although the present invention has been described with the stack-piezo having a square cross section, and the piston having a round cross-section, it will be appreciated by one of ordinary skill in the art that the shape of the cross-section is not so limited, and that the area where the stack-piezo and the piston contact each other need only be similarly sized to efficiently transmit blocking force to each component.

While the invention has been described in detail with reference to preferred embodiments thereof, it will be apparent to one skilled in the art that various changes can be made, and equivalents employed, without departing from the scope of the invention.

What is claimed is:

1. A power conversion module comprising:
a housing having a proximal end and a distal end;
a mechanical stop mounted in the distal end of the housing;
a moveable piston disposed within the housing that divides the housing into first and second chambers;
a stack-piezo disposed within the first chamber between the mechanical stop and the piston;
a first sealing means disposed between the piston and the housing;
a shaft extending through an opening in the proximal end of the housing into the interior of the second chamber;
a second sealing means disposed between the shaft and the housing; and
a non compressible fluid contained within the second chamber.

2. The power conversion module of claim 1, wherein the mechanical stop is selected from the group consisting of: a plug, and a spring ring.

3. The power conversion module of claim 2, wherein the first sealing means is selected from the group consisting of: a step and seal combination, and a groove and ring seal combination.

4. The power conversion module of claim 2, wherein the second chamber further comprises a channel positioned opposite the piston.

5. The power conversion module of claim 1, wherein the second sealing means is an o-ring.

6. The power conversion module of claim 5, wherein the o-ring is made of a material selected from the group consisting of: rubber, and a reinforced wax and cotton combination.

7. The power conversion module of claim 1 wherein the mechanical stop exerts a bias pressure on the stack-piezo ranging from approximately 1 to 10 newtons.

8. The power conversion module of claim 1, wherein the housing is made from a material selected from the group consisting of: hard plastic and metal.

9. The power conversion module of claim 1 wherein the non compressible fluid is hydraulic fluid.

10. The power conversion module of claim 1, wherein the second chamber has a distal diameter within the range of from approximately 3 millimeters to 50 mm, and the shaft has a diameter in the range of from approximately 0.4 millimeters to 12 millimeters.

11. The power conversion module of claim 1 further comprising a biasing means in contact with the proximal end of the shaft, wherein the biasing means exerts pressure on the shaft.

12. The power conversion module of claim 11 wherein the biasing means is selected from the group consisting of: a return spring, an air pressure source, and a water pressure source.

13. The power conversion module of claim 1 further comprising an electronic driver connected to the stack-piezo with connecting wires.

14. The power conversion module of claim 1, the second chamber further comprising:
at least one front wall;
a small opening in the proximal end of the front wall; and
at least one sidewall;
wherein an angle θ measured between the at least one front wall and at least one side wall is in the range of from 90 degrees to approximately 150 degrees.

15. The power conversion module of claim 1 further comprising a shaft guard disposed at the proximal end of the housing having an opening with a diameter slightly larger than a diameter of the shaft, allowing the shaft to move freely through the opening in the shaft guard.

16. A power conversion module comprising:
a housing;
a first chamber containing a stack piezo;
a second chamber containing a non compressible fluid comprising
at least one front wall having an opening there through; and
at least one sidewall; wherein
an angle θ measured between the at least one front wall and the at least one side wall is within the range of from approximately 130 to approximately 150 degrees;
a seal disposed between the first and second chamber; and
a shaft extending into the second chamber through the opening;
wherein the stack piezo, sealed chamber, and shaft are longitudinally aligned.

17. The power conversion module of claim 16 wherein the angle θ measures 145 degrees.

18. The power conversion module of claim 16, further comprising a piston disposed between the stack-piezo and the second chamber.

19. The power conversion module of claim 11, further comprising a shaft guard disposed at the proximal end of the housing having an opening with a diameter slightly larger than a diameter of the shaft, allowing the shaft to move freely through the opening in the shaft guard.

20. The power conversion module of claim 11 further comprising a third chamber, wherein the biasing means is disposed within the third chamber.

21. The power conversion module of 11, wherein the biasing means comprises a lever.

22. The power conversion module of claim 11 further comprising:
an electronic driver electrically connected to the stack-piezo; and
an additional chamber having the electronic driver disposed therein.

23. The power conversion module of claim 1, wherein the shaft has a diameter in the range of from approximately 0.4 millimeters to approximately 12 millimeters.
